(19) United States
(12) Patent Application Publication
(10) Pub. No.: US 2026/0033119 A1
(43) Pub. Date: Jan. 29, 2026

(54) A PHOTONIC-ORGANIC ELECTROCHEMICAL TRANSISTOR

(71) Applicant: Purdue Research Foundation, West Lafayette, IN (US)

(72) Inventors: Ke CHEN, Mountain view, CA (US); Jianguo MEI, West Lafayette, IN (US)

(73) Assignee: Purdue Research Foundation, West Lafayette, IN (US)

(21) Appl. No.: 19/143,681

(22) PCT Filed: Mar. 7, 2024
(86) PCT No.: PCT/US24/18965

§ 371 Date: Jun. 26, 2025

Related U.S. Application Data
(60) Provisional application No. 63/450,996, filed on Mar. 9, 2023.

(51) Int. Cl. H10K 30/65; H01G 9/20; H10K 30/30; H10K 85/20

(52) U.S. Cl. CPC H10K 30/65; H01G 9/2013; H10K 30/30; H10K 85/215

(57) ABSTRACT

A photonic-organic electrochemical transistor (POECT), including a substrate, three terminals including a gate, a drain, and a source disposed over the substrate, wherein the space between the drain and the source forms a channel, and an electrolyte in fluid and electrical communication with the gate and the channel, wherein the channel is formed of a photoactive layer composed of donor-acceptor bulk-heterojunction interfaces.

### CROSS-REFERENCE TO RELATED APPLICATIONS

This patent application claims priority to a U.S. provisional patent application Ser./N 63/450,996 filed Mar. 9, 2023, contents of which are hereby incorporated by reference in its entirety into the present disclosure.

### STATEMENT REGARDING GOVERNMENT FUNDING

None.

### TECHNICAL FIELD

The present disclosure generally relates to electronic switches, and in particular to a new type of electrochemical transistor that is co-activated by light.

### BACKGROUND

This section introduces aspects that may help facilitate a better understanding of the disclosure. Accordingly, these statements are to be read in this light and are not to be understood as admissions about what is or is not prior art.

Bioinspired electronics are devices or systems that can emulate the functions of living things. To develop future advanced bioelectronics or humanoid robots, there has been a surge of interest in constructing synaptic or neuromorphic devices that can think and memorize like human brains. With the advancement of brain-machine interfaces and prosthetics, research emerges to interface these intelligent devices with living systems. Organic synaptic devices are particularly suitable for this purpose due to their mechanical comfortability, biocompatibility and responsivity to analytes in biological media. In the past two decades, major efforts have been made to investigate organic electronic synapses with both input and output as electrical signals.

To date, three-terminal field-effect transistors (FETs) are one of major platforms for organic biosensors. In the devices, the photon-induced charge separation, transport, and trapping at channel/dielectric interfaces are regarded as the primary working mechanism for biosensors, e.g., photonic synaptic sensors, behaviors. Based on this mechanism, the biosensors can emulate biological functions such as short-term plasticity (STP), long-term plasticity (LTP), and spiking time-dependent plasticity (STDP). However, there are some intrinsic challenges in implementation of this type of devices. For example, achieving linear multilevel conductance states is still difficult with FETs, due to the charge screening effects at the interfaces. The photocurrents of FET devices are often limited even at high programming voltages, which results in ambiguous short term/long term memory signals and limits their utilities in high density computing. Therefore, it is crucial to have a device platform that can generate considerable photocurrent at low programming voltages, provide multilevel conductance states, and enable light-gated ionic/electronic coupling for constructing future electronics-biological interfaces.

Therefore, there is an unmet need for a novel device that can generate switching with a memory function adaptable for use in biosensors.

### SUMMARY

To be completed at the end of the drafting process.

### BRIEF DESCRIPTION OF DRAWINGS

FIG. 1a provides top view and sideview schematics of a photonic synaptic device according to the present disclosure.

FIG. 1b is a schematic of the photonic synaptic device of the present disclosure with various components called out as well as a series of voltage and current graphs depicting the operation of the photonic synaptic device of the present disclosure.

FIG. 2a is a graph of characteristic photonic responses of the device of the present disclosure with light writing (purple region) and voltage erasing (grey regions).

FIG. 2b provides three representative cycles of light memory writing (V_{G}=−0.6 V, V_{DS}=−0.8 V) and voltage erasing (V_{G}=0.4 V, V_{DS}=−0.8 V).

FIG. 2c is a graph of −ΔI_{DS} in μA vs. pulse umber, for the device of the present disclosure where current was written by shortened light pulses (7.0 mW/cm², tₚ=0.04 s, Δt=0.04 s), achieving high-density linear weight updates, and erased by gate volage pulses (V_{G}=0.4 V).

FIG. 2d is a graph of −ΔI_{DS} in μA vs. light intensity in mW/cm² which shows the light intensity-modulated photonic response.

FIG. 2e is a graph of −ΔI_{DS} in μA vs. wavelength in nm which shows light wavelength-modulated photonic response.

FIG. 2f is a graph of −ΔI_{DS} in μA vs. |V_{G}| in V which shows gate voltage-modulated photonic response.

FIG. 2g is a graph of −ΔI_{DS} in μA vs. light intensity in mW/cm² which shows mimicking the optical sensing towards different illumination conditions in the human eye.

FIG. 2h provides graphs of −ΔI_{DS} in μA vs. light pulse number which shows the evaluation of the distinguishability and reproducibility of the weight update in three cycles depicted in FIG. 2b.

FIG. 2i is a graph of standard deviation vs. −ΔI_{DS} in μA which provides standard deviation vs. photocurrent change.

FIG. 2j provides graphs of −I_{DS} in μA vs. time in seconds with a zoomed in plot to show stair-step activity.

FIG. 2k provides graphs of −ΔI_{DS} in μA vs. pulse numbers and vs. days, which show continuous cycles of writing and erasing as well as photonic responses of the device of the present disclosure that was stored and tested in ambient conditions across one week.

FIG. 2l provides graphs of normalized −ΔI_{DS} in μA (current change) over 10,000 cycles of switch on (−0.8 V) and off (0.1 V), with two panels showing the zoom-in views of current change in the first and last 50 cycles, and a graph of ΔI_{DS} in μA vs. test number, showing the photonic response of the device of the present disclosure at the beginning, after 1000, 3000, 6000, and 10,000 electrochemical cycles.

FIG. 2m is a plot of ΔI_{DS} in μA vs. time in seconds, where the current read at the dashed lines corresponds to the transient and memory current, respectively.

FIG. 2n is a graph of −ΔI_{DS} in μA vs. time in seconds for exposure of the device to different wavelengths in which current read at the dashed lines corresponds to the transient and memory current, respectively.

FIG. 20 is a plot of normalized absorbance vs. wavelength in nm providing absorption spectrum of the P₃HT/PCBM thin film.

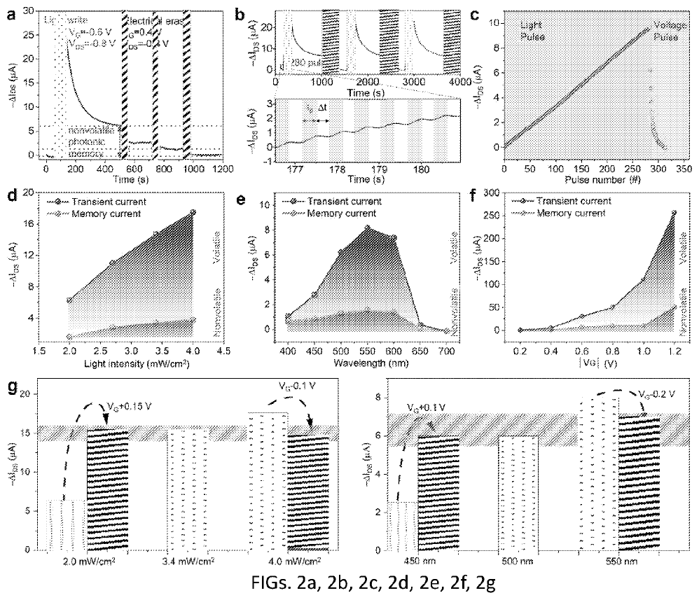

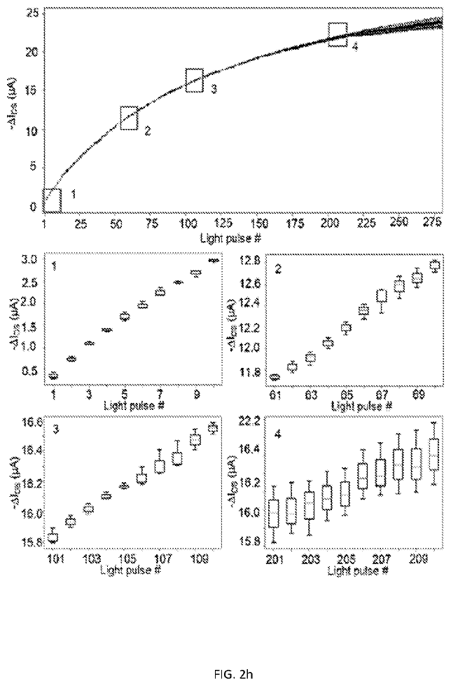

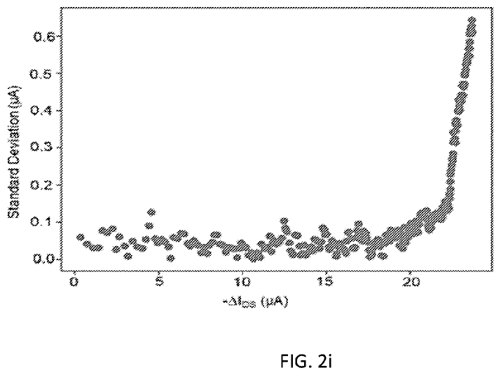

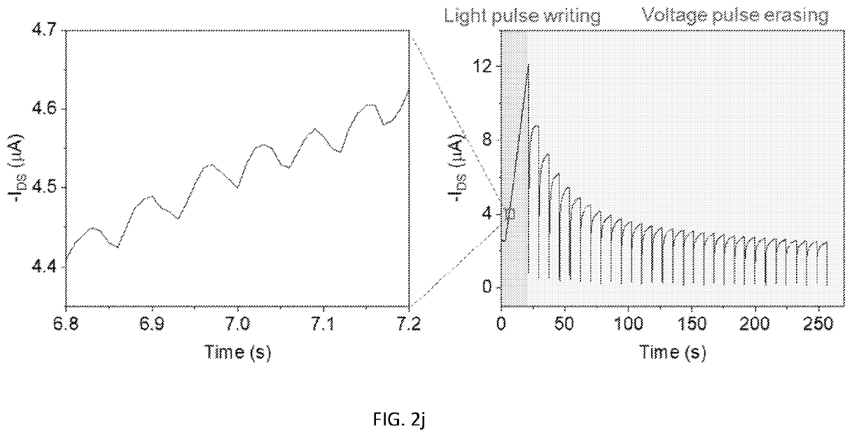

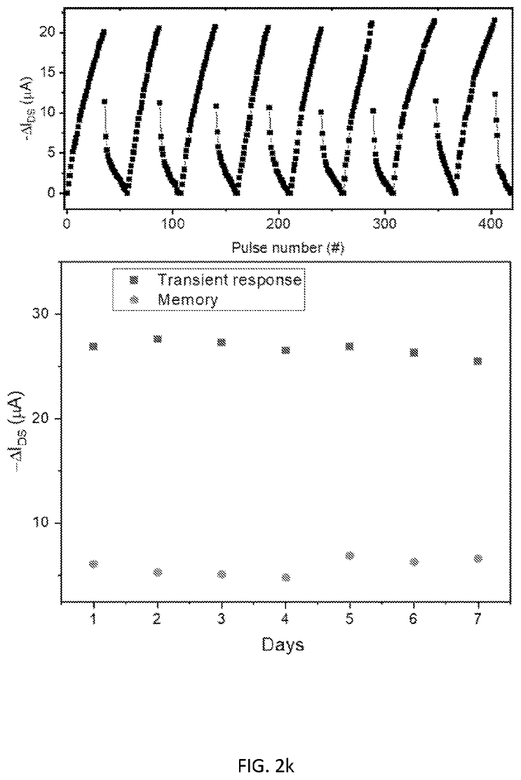

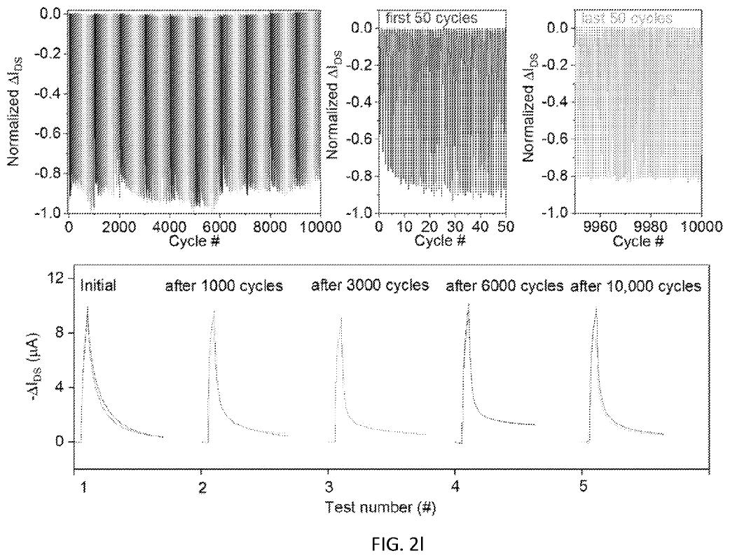

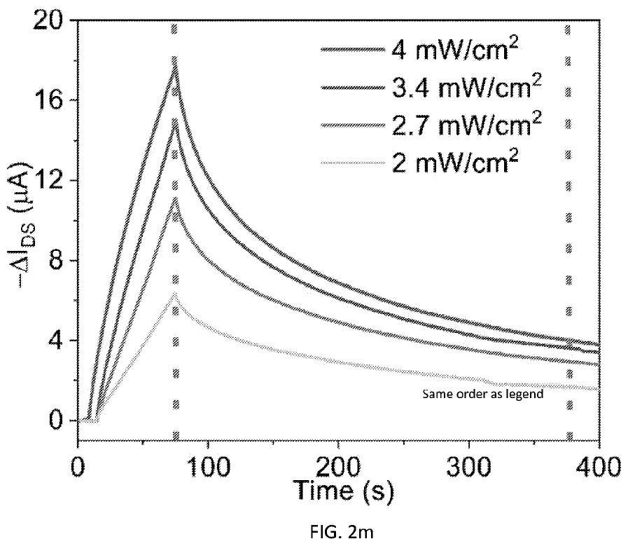

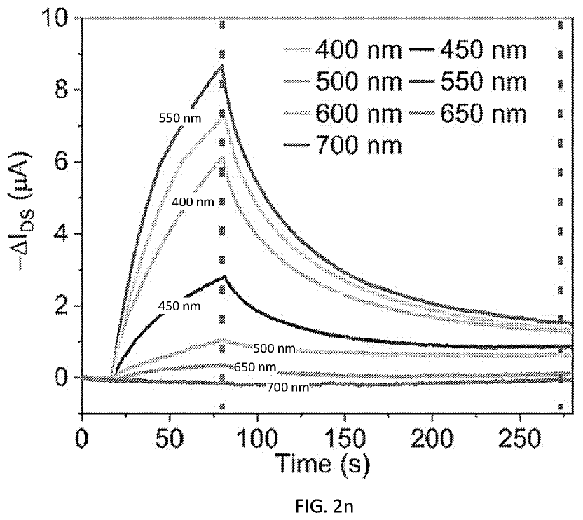

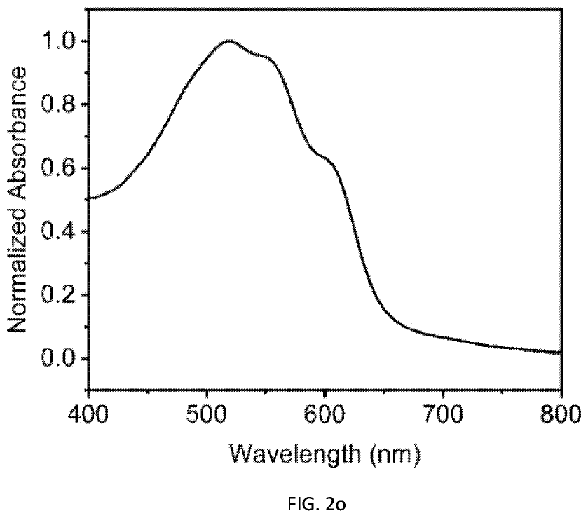

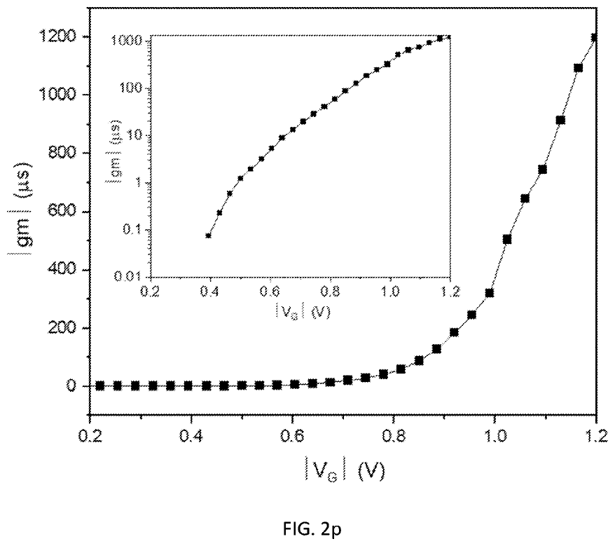

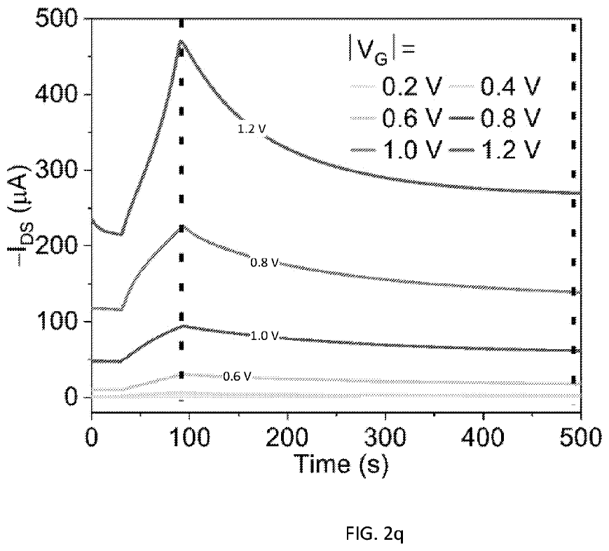

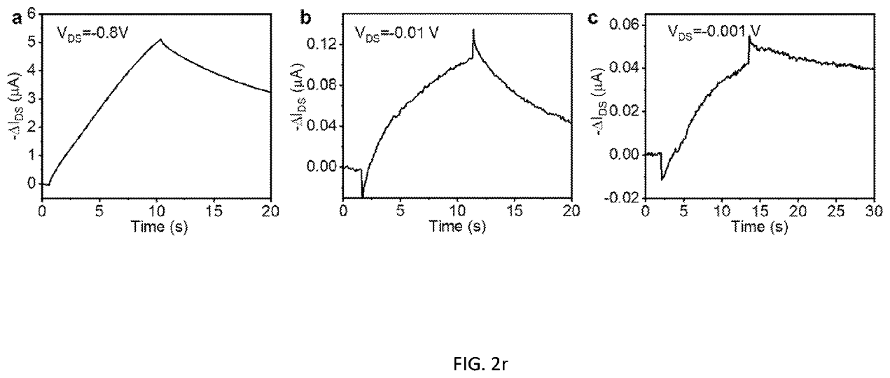

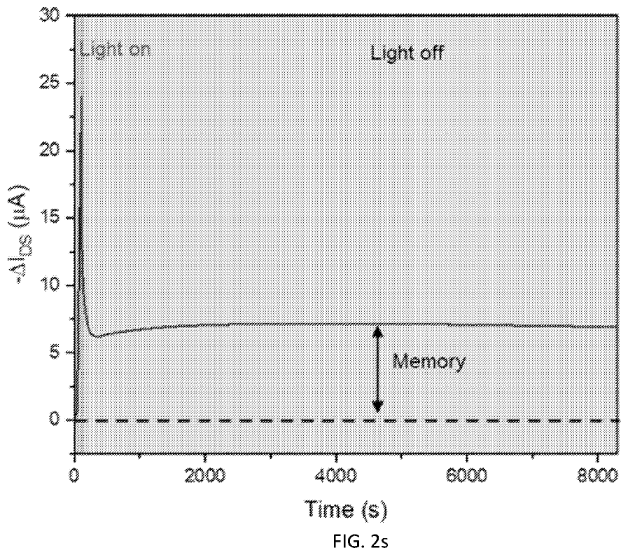

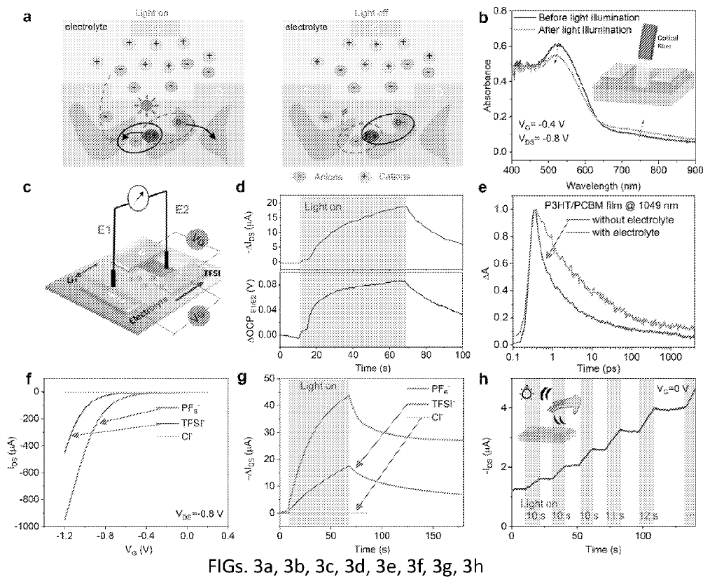

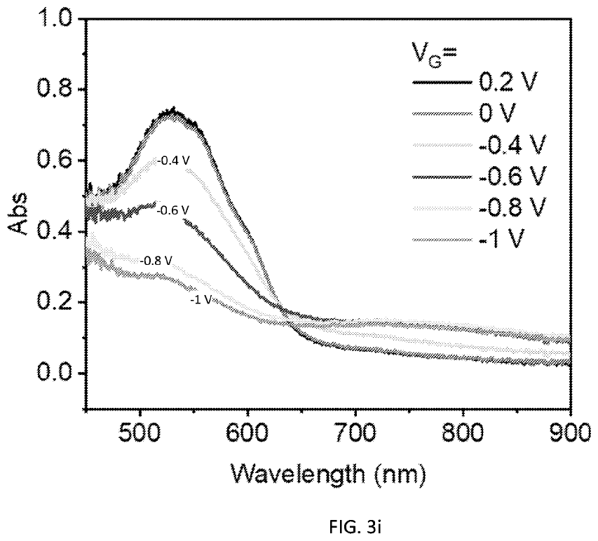

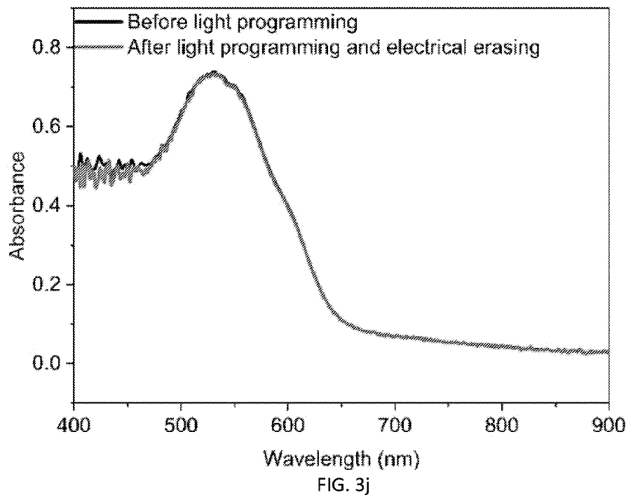

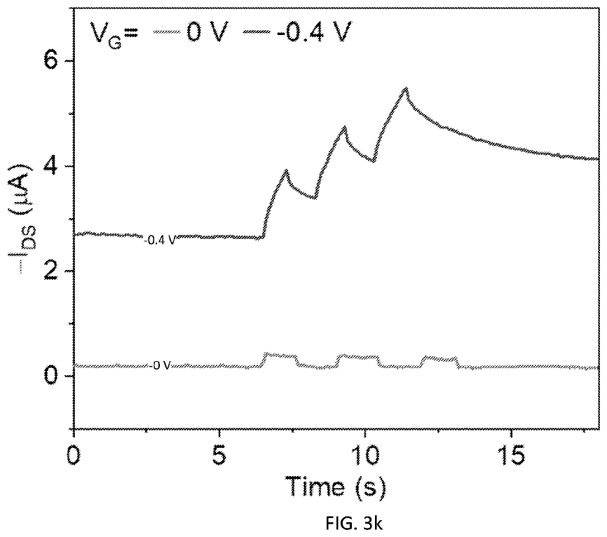

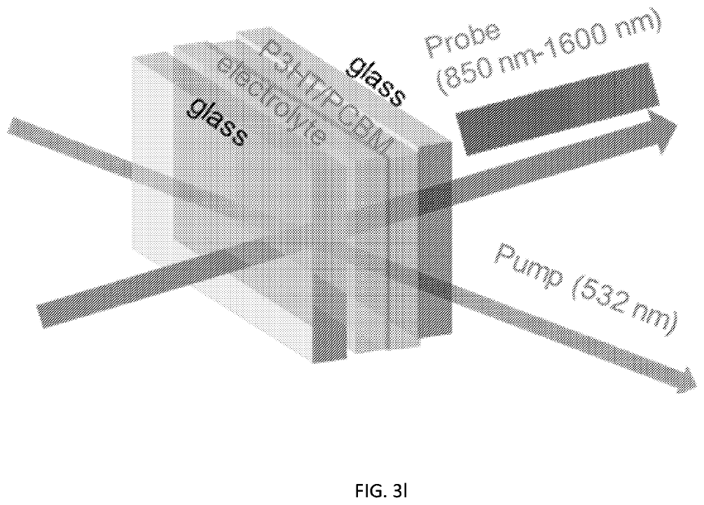

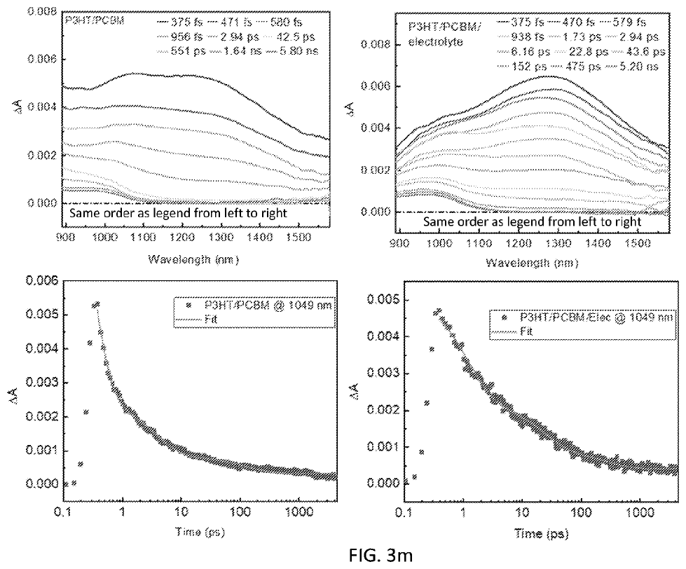

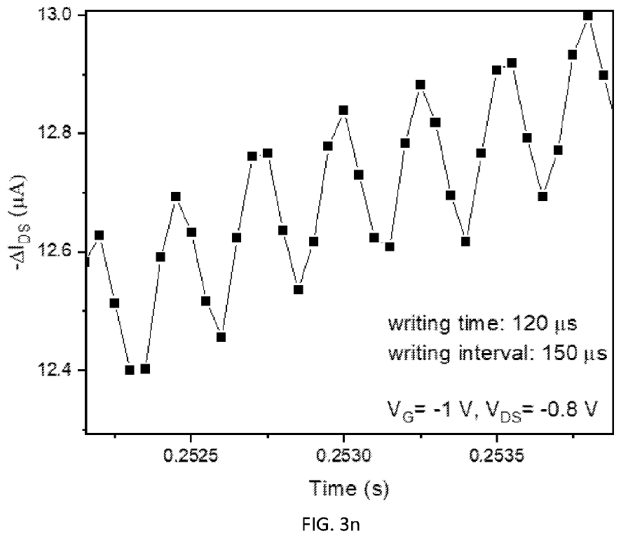

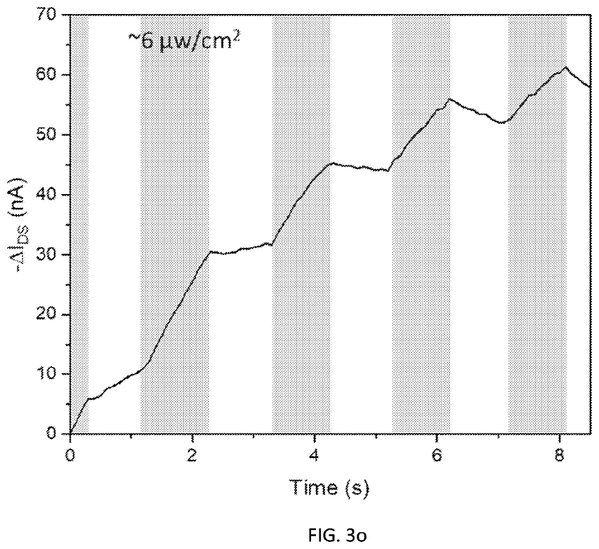

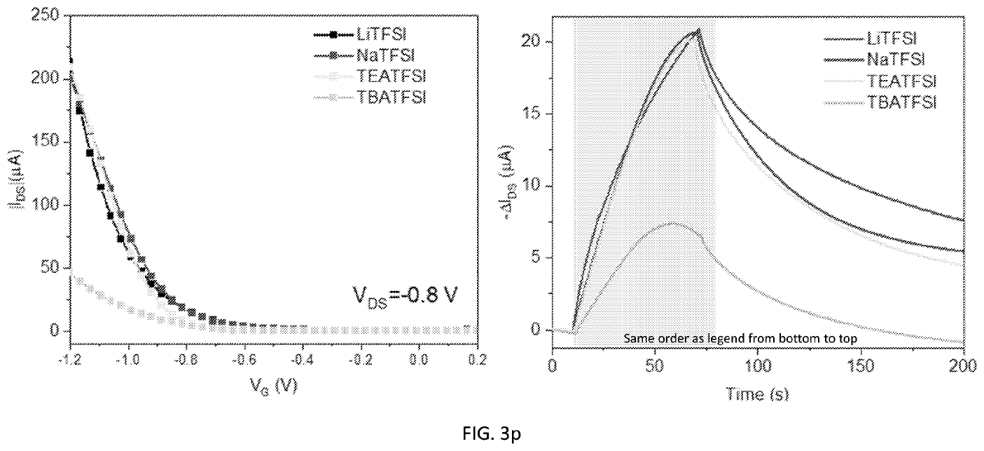

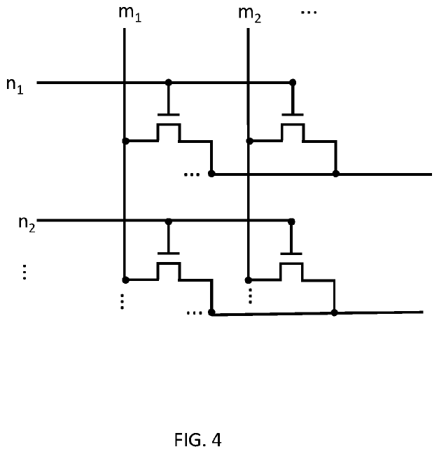

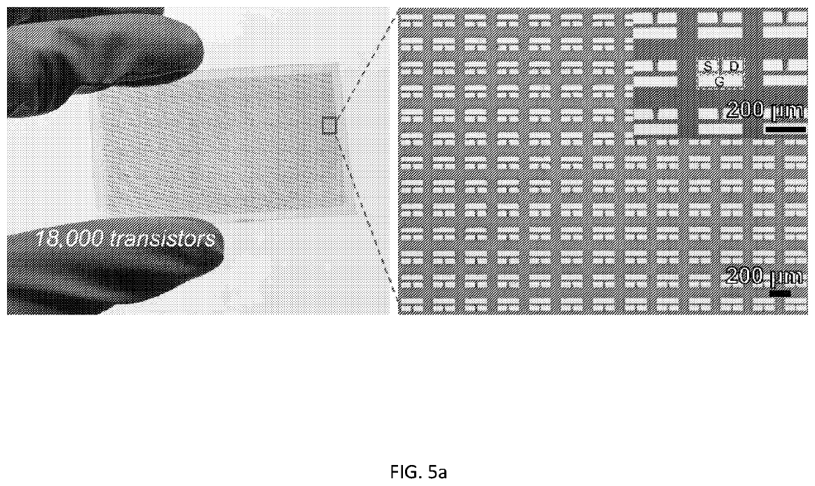

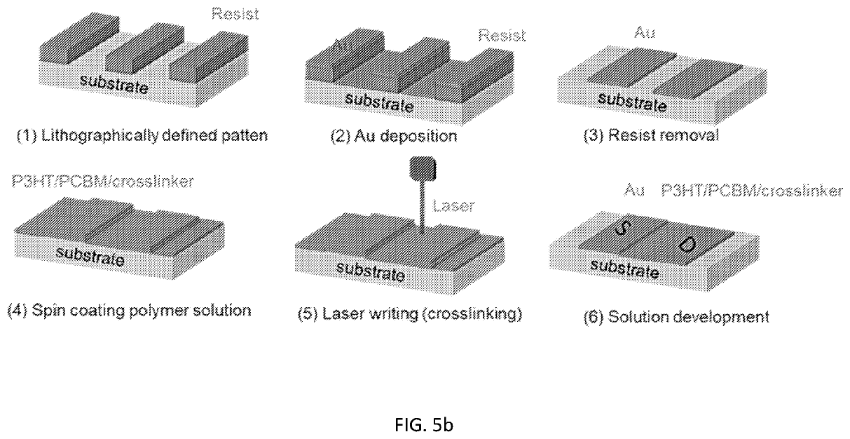

FIG. 2p provides transconductance values of the device of the present disclosure, wherein the inset figure shows the trend with log-scale of the transconductance values.

FIG. 2q is a graph of −I_{DS} in μA vs. time in seconds for various gate voltages.

FIG. 2r provides graphs of −ΔI_{DS} in μA vs. time for various V_{DS} voltages which show that a decrease of the drain voltage (from −0.8 V to −0.001 V) significantly reduces photocurrent, while the device maintains the typical photonic response and memory behavior.

FIG. 2s is a graph of −ΔI_{DS} in μA vs. time in seconds demonstrating memory retention characteristics of the device after responding to a 60-second light pulse.

FIG. 3a is a schematic illustration showing photon-modulated electrochemical doping, in which light-induced charge carriers in the bulk heterojunctions leads to ion transport from the electrolyte for charge compensation are shown.

FIG. 3b is a schematic and graph used to validate the photon-modulated electrochemical doping, in which an in-situ spectroscopic experiment is performed before and after light exposure.

FIG. 3c is a schematic illustration of a five-electrode electrochemical cell, where two extra electrodes (E1, E2, e.g., Pt electrodes) are added to the photonic synaptic device of the present disclosure to monitor the ion migration.

FIG. 3d are graphs that provide simultaneous channel current change (I_{DS}) in μA and open circuit potential (OCP_{E1/E2}) in V both vs. time in seconds showing change in response to light illumination.

FIG. 3e is a graph showing [6,6]-phenyl C61-butyric acid methylester (PCBM) anion radical/polaron transient absorption decay kinetic trace of pristine P₃HT/PCBM film and the film with electrolyte (as called out in the figure)—the plots are normalized to facilitate comparison.

FIG. 3f provides a graph of −I_{DS} in μA vs. V_{G} in Volts showing the transfer characteristics of the device.

FIG. 3g is a graph of −ΔI_{DS} in μA vs. time in seconds providing an illustration of photonic response at V_{G}=−0.6 V and V_{DS}=−0.8 V of the device in different electrolytes.

FIG. 3h is a graph of −I_{DS} in μA vs. time in seconds providing an illustration of photonic response of the device to hand waves in an ambient light environment with LiPF₆ based gcl electrolyte.

FIG. 3i is a graph showing results from a spectroelectrochemistry experiment.

FIG. 3j is a graph of absorbance vs. wavelength in nm illustrating that the photon-modulated electrochemical doping is accompanied by ion transport which thereby demonstrates the device spectrum can be recovered to pristine states with the application of a reverse gate voltage.

FIG. 3k is a graph of −I_{DS} in μA vs. time in seconds illustrating the photonic response to three light pulses at various gate voltages.

FIG. 3l is a schematic illustration of transient spectroscopy measurement.

FIG. 3m provides graphs of transient spectra of P₃HT/PCBM and P₃HT/PCBM/electrolyte at various decay times and decay dynamics of P₃HT/PCBM and P₃HT/PCBM/electrolyte which are fitted using triexponential equations with a constant non-decaying component.

FIG. 3n is graph of −ΔI_{DS} in μA vs. time in seconds, in which drain current in response to fast light pulses.

FIG. 3o a graph of −ΔI_{DS} in μA vs. time in seconds illustrating photonic response to light pulses with light intensity of 6 μw/cm².

FIG. 3p provides graphs of absolute value of I_{DS} in μA vs. V_{G} in volts and a graph of −ΔI_{DS} in μA vs. time in seconds are provided illustrating photonic response to light pulses which thereby demonstrates transfer characteristics and photonic response of the devices in different electrolytes.

FIG. 4 is a schematic of a network of the devices of the present disclosure in connectivity with each other to form an array for various applications.

FIG. 5a is a fabricated device array with 18,000 transistors on a 2.5×5 cm² glass substrate arranged in an array.

FIG. 5b is a schematic of a device fabrication process of the device of the present disclosure.

### DETAILED DESCRIPTION

For the purposes of promoting an understanding of the principles in the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

A novel device that can generate switching with a memory function adaptable for use in biosensors is described herein. Towards this end, a photonic-organic electrochemical transistor (POECT) device is described herein, adapted to receive voltage and light as input and provide electronic switching behavior with memory. Specifically, an organic electrochemical photonic device is disclosed including a photoactive layer composed of donor-acceptor bulk-heterojunction interfaces into a channel of an organic electrochemical transistors (OECTs). The resulting device presents significant photocurrent at low operating voltage (<1 V), enabling high-density nonvolatile conductance states for various applications, e.g., neuromorphic computing. The nonvolatile current is regulated by both light intensity and wavelength across the entire visible spectrum, demonstrating the capabilities of utilizing the POECT device for a wide range of biosensor applications, e.g., perceiving and memorizing various visual information applied to the device.

The POECT device of the present disclosure is a three-terminal device, including a gate adapted to receive a voltage for activating the device; a drain; and a source, wherein the source is typically coupled to ground and the drain is coupled to a voltage source via a load. When a voltage is applied to the gate, the device turns on allowing a drain to source current from the voltage source. The drain to source area is disposed over a channel that is made from a photoactive layer composed of donor-acceptor bulk-heterojunction interfaces. Thus, application of light i) enhances the drain to source current, and ii) provides a memory function. In other words, when the light is removed from the channel, the drain to source current retains some or all of its enhanced current, and when the light is re-established at the channel, the drain to source current enhances again from the previous enhanced position rather than from an initial position before light was applied. The POECT device of the present disclosure can also be reset, i.e., the memory erased by applying the proper voltage to the gate.

In contrast to electrical signal, light allows ultrafast signal transmission with limited crosstalk, enabling a computational domain that is inaccessible by pure electrical devices. Light has also been widely used as the stimulation method in bioelectronics to regulate cell activity due to its wireless communication with high spatial and temporal resolution. Thus, the POECT device of the present disclosure is adapted to provide a light-gated fast acting device usable in a variety of applications, including biosensors, e.g., a synaptic device (photonic synapses) for a variety of biological applications, e.g., neuromorphic computing and other biological applications. Furthermore, the addition of light signal acquiring capability to traditional electrical synaptic devices will offer the opportunity to emulate the function of biological elements, e.g., human retina for image preprocessing and recognition.

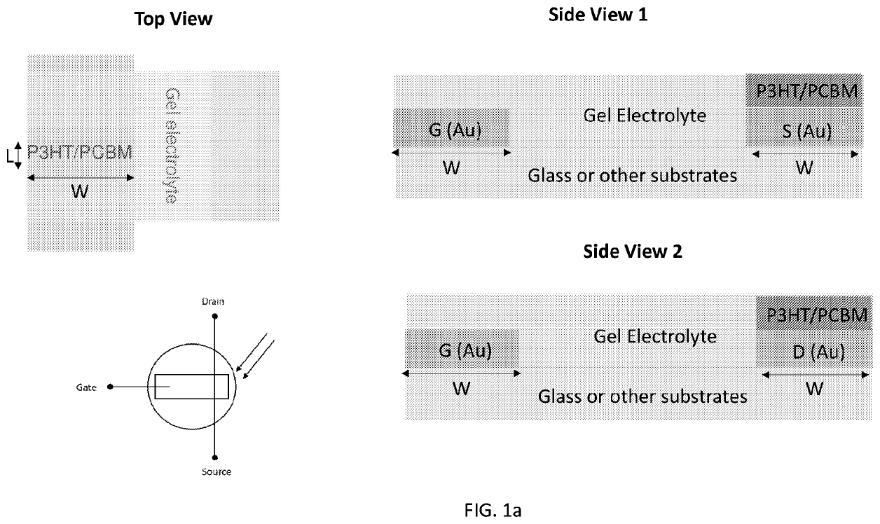

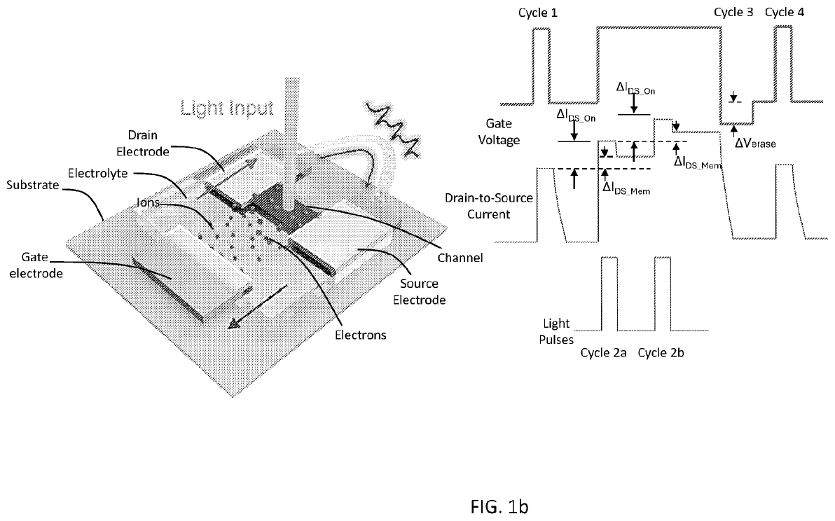

Referring to FIG. 1a, sideview schematics, a top view, and a symbol of the POECT device according to the present disclosure are provided. The POECT device includes a substrate, three terminals (or electrodes) including gate, drain, and source, an electrolyte (e.g., a gel electrolyte) disposed between and encasing the terminals, and a channel disposed between or over the drain and source terminals. The electrolyte provides an ion transport mechanism between the gate terminal and the channel. An example electrolyte material is Poly(ethylene glycol) diacrylate (PEGDA)/lithium bis(trifluoromethane) sulfonimide (LiTFSI)/propylene carbonate (PC) utilized in a gel form. Other suitable electrolytes may be used, as is known to a person having ordinary skill in the art. The area between and under the drain and source terminals is occupied by a photovoltaic material. Such material is a combination of poly(3-hexylthiophene) (P₃HT) and [6,6]-phenyl C61-butyric acid methylester (PCBM), according to one embodiment.

Referring to FIG. 1b, a schematic of the POECT device of the present disclosure is shown with various components called out. In the example shown in FIG. 1b, the substrate is made of glass, however, a number of other substrates are also possible, as known to a person having ordinary skill in the art. Furthermore, the three terminals (gate, drain, and source) are made of gold, while other conductive materials are also possible, as known to a person having ordinary skill in the art. The memory aspect of the POECT device of the present disclosure is demonstrated in FIG. 1b, wherein as optical pulses are introduced to the channel, the signal intensity of the POECT device increases in a non-volatile manner.

Additionally, FIG. 1b provides a series of voltage and current graphs that are used to depict the operation of the POECT device of the present disclosure. In particular, by applying a voltage to the gate, the device is turned on and is allowed to establish a channel to thereby allow conduction of a current between the drain and the source terminals governed by a load coupled to the drain or source terminals, as is known to a person having ordinary skill in the art. In this mode the device is deemed as being on. When the gate voltage is removed, the device turns off, as indicated by a decaying drain-to-source current. This behavior is shown as Cycle 1. However, if a light pulse is applied during cycle 2a when the device is turned on (i.e., with the gate voltage is on and stable), the device turns back on, in which case the drain-to-source current increases above the drain-to-source current in the on state of cycle 1. This increase in current is shown as ΔI_{DS_on}. After the light is turned off, the drain-to-source current decays but remains above the on state of cycle 1. This difference is referred to as ΔI_{DS_Mem} which can be used to establish the memory nature of the POETC device of the present disclosure. In cycle 2b, another light pulse is applied, which again causes the drain-to-source current to elevate above the drain-to-source current of cycle 2a by about the same ΔI_{DS_on} shown in cycle 2a. Again, once the light is turned off, the drain-to-source current decays, but this current remains above the on state of cycle 2a, again having a difference of about ΔI_{DS_Mem} which again can be used to establish the memory nature of the POETC device of the present disclosure. In cycle 3, shown in FIG. 1b, the gate voltage is reversed (as depicted by ΔVₑᵣₐₛₑ) which causes the memory aspect of the POETC device to be erased. Thus, in cycle 4, the device returns to its operation as shown in cycle 1.

In order to show the effectiveness of the POECT device of the present disclosure, (a P₃HT and PCBM mixture was used as the photoactive material and deposited in the channel, due to its well-stablished optoelectronic properties and electrochemical stability. Poly(ethylene glycol) diacrylate (PEGDA)/lithium bis(trifluoromethane) sulfonimide (LiTFSI)/propylene carbonate (PC) was utilized as the gel electrolyte since it offers good ion conductivity and processability.

With the obtained device, the photonic response was first evaluated using a 70-second white light pulse with an intensity of 7.0 mW/cm² under a gate voltage of −0.6 V and a drain voltage of −0.8 V, as shown in FIG. 2a, which is a graph of characteristic photonic responses of the device with light writing (dotted region) and voltage erasing (crosshatched regions). When a light pulse was applied to the device, a noticeable current increase (26.7 μA) was observed; it then decayed and subsequently maintained at around 6.0 μA after the light turned off. The magnitude of difference between the steady state current after the light programming and before the light programming was defined as nonvolatile photonic memory. This nonvolatile current can be stepwise erased by the application of three reverse gate electrical pulses (0.4 V), as shown in the grey regions, which demonstrates the capability of photonic writing and electrical erasing of the synaptic device. Referring to FIG. 2b, three representative cycles of light memory writing (V_{G}=−0.6 V, V_{DS}=−0.8 V) and voltage erasing (V_{G}=0.4 V, V_{DS}=−0.8 V) are shown. In each writing process, consecutive light pulses (7.0 mW/cm²) with the duration time (tₚ) of 0.4 s and interval time (Δt) of 0.23 s were applied. Zoom-in view shows the detailed dynamic current change in response to the light pulses. Referring to FIG. 2c, the POECT device current was written by shortened light pulses (7.0 mW/cm², tₚ=0.04 s, Δt=0.04 s), achieving high-density linear weight updates, and erased by gate volage pulses (V_{G}=0.4 V). FIG. 2d shows the light intensity-modulated photonic response. FIG. 2e shows light wavelength-modulated photonic response. All applied light with varied wavelengths has the same light intensity of 2.1 mW/cm². FIG. 2f shows gate voltage-modulated photonic response (7.0 mW/cm², 60 s). FIG. 2g shows mimicking the optical sensing towards different illumination conditions in the human eye. By tunning gate voltage (V_{G}), the photonic response under varying light intensity (left dotted bars) and light wavelength (right dotted bars) can be modulated to desirable levels (crosshatched bars). V_{G}=−0.6 V, V_{DS}=−0.8 V.

Referring to FIG. 2b, distinct nonvolatile conductance states were observed, as seen in the zoom-in view. The current written by light can be erased by a reverse voltage pulse. It clearly exhibits a writing-and-erasing cycling stability. The reproducibility and distinguishability of weight update in these three cycles were also examined in FIG. 2h, which show graphs of −ΔI_{DS} in μA vs. light pulses (in numbers). FIG. 2h provides the evaluation of the distinguishability and reproducibility of the weight update in three cycles depicted in FIG. 2b. The lower panels show the zoom-in views of region 1-4. Within a linear current increase range (0-15 μA), each state (indicated by organ line) is clearly distinct from others, with a small variation of around 0.1 μA. FIG. 2i is a graph of standard deviation vs. −ΔI_{DS} in μA which provides standard deviation vs. photocurrent change.

Within a linear current increase range (0-15 μA), each state is clearly distinct from others, with a small standard deviation of about 0.1 μA. Thus, we further shortened pulses duration and interval time (tₚ=0.04 s, Δt=0.04 s) and achieved 280 distinct states with excellent linear weight updates in the dynamic current range of 10 μA, as shown in FIG. 2c. This indicates high density of linear conductance states could be achieved with our device. The current written by light pulses were erased by consecutive reverse voltage pulses with an exponential decay manner. The detailed dynamic current change of this writing-and-erasing process are shown in FIG. 2j, which provides a graph of −I_{DS} in μA vs. time in seconds with a zoomed in plot to show stair-step activity. Specifically, FIG. 2j shows photonic response under the application of consecutive light pulses and reverse voltage pulses. The light pulses have the intensity of 7.0 mW/cm², duration time of 0.04 s, and interval time of 0.04 s. The voltage pulses (0.4V) have the duration time of 0.1 s and interval time of 8 s. Moreover, the device exhibited good writing and erasing durability, cycling stability (over 10,000 cycles), as well as constant performance over long storage time, as shown in FIGS. 2k and 2l. FIG. 2k provides graphs of −ΔI_{DS} in μA vs. pulse numbers and vs. days, which show continuous cycles of writing and erasing as well as photonic responses of the POECT device that was stored and tested in ambient conditions across one week. FIG. 2l provides graphs of normalized −ΔI_{DS} in μA (current change) over 10,000 cycles of switch on (−0.8 V) and off (0.1 V), with two panels showing the zoom-in views of current change in the first and last 50 cycles; and a graph of ΔI_{DS} in μA vs. test number, showing the photonic response of the POECT device at the beginning, after 1000, 3000, 6000, and 10,000 electrochemical cycles.

The factors that could influence the photonic response of the POECT device of the present disclosure are investigated. First, the impact of light intensity was investigated. The device was exposed to four separate light pulses with same duration (60 s) but distinct intensities. The current response as a function of light intensity is extracted from FIG. 2m (which is a plot of ΔI_{DS} in μA vs. time in seconds, where the current read at the dashed lines corresponds to the transient and memory current, respectively) and plotted in FIG. 2d, in which the transient current was recorded immediately when the light was turned off, and the memory current was recorded 300 s later. It should be noted that higher photon-induced transient current leads to higher memory current, however there is no linear relationship between the two. Thus, the purple area in FIG. 2d represents the photonic volatile current while the blue area indicates the nonvolatile current. It can be seen that both the volatile and nonvolatile currents increase with the light intensity, indicating the device's conductance states can be continuously tuned, and thus selective based on light intensity. Additionally, the POECT device of the present disclosure also behaves correspondingly in response to various light wavelengths as shown in FIG. 2e, above, and FIG. 2n (which is a graph of −ΔI_{DS} in μA vs. time in seconds for exposure of the device to different wavelengths in which current read at the dashed lines corresponds to the transient and memory current, respectively), according to the absorption profile of the photoactive material shown in FIG. 2o, which is a plot of normalized absorbance vs. wavelength in nm providing absorption spectrum of the P₃HT/PCBM thin film. Both observations indicate the device can perceive and memorize different optical information, including light intensity and color, selectively. In addition to the light input, the photonic response of the device can be regulated by the gate voltage. As demonstrated in FIG. 2f, when the device was exposed with a light pulse (60 s, 7.0 mW/cm²), both the volatile and nonvolatile currents rose with the increased gate voltage, possibly due to enhanced transconductance as provided in FIG. 2p, which provides transconductance values of the POECT device, wherein the inset figure shows the trend with log-scale of the transconductance values-higher transconductance indicates that the device's signal amplification and sensitivity are enhanced). Especially, at a gate voltage of −1.2 V, a dynamic current range of 258 μA was achieved as shown in FIG. 2q, which is a graph of −I_{DS} in μA vs. time in seconds for various gate voltages. The current read at the dashed lines corresponds to the transient and memory current, respectively. The modulation of the gate voltage also enables the adjustment of photonic response according to varying illumination conditions. For example, in FIG. 2g, the photonic current under different light wavelengths and intensities can be modulated to be almost identical level (grey regions) by setting appropriate gate voltages. This photonic behavior is similar to various biological elements, e.g., human iris, which can control the light perception in various environment by regulating the pupil sizes. Aside from the gate voltage, the drain voltage can also be used to tune the photonic response. FIG. 2r provides graphs of −ΔI_{DS} in μA vs. time for various V_{DS} voltages which show that a decrease of the drain voltage (from −0.8 V to −0.001 V) significantly reduces photocurrent, while the device maintains the typical photonic response and memory behavior. The applied gate voltages for each Vos trial is the same (−0.6 V). It should be noted that the power consumption of the device can be reduced by operating at lower drain voltage. The long-term retention of device memory over more than 2 hours was demonstrated in FIG. 2s, which is a graph of −ΔI_{DS} in μA vs. time in seconds demonstrating memory retention characteristics of the device after responding to a 60-second light pulse.

The POECT device of the present disclosure is enabled by photon-modulated electrochemical doping. Specifically, light absorption by donor-acceptor heterojunction produces charge carriers, which perturb electrochemical doping and is accompanied by the anion transport from electrolyte for charge compensation in the channel, as shown in FIG. 3a, which is a schematic illustration showing photon-modulated electrochemical doping, in which light-induced charge carriers in the bulk heterojunctions leads to ion transport from the electrolyte for charge compensation. After the light illumination, the presence of anions prohibits an immediate charge recombination. Thus, the higher carrier concentrations resulted from photon-modulated doping is detected as an increased drain current. When the light is switched off, the presence of anions around the doped P₃HT prohibits an immediate charge recombination, leading to a slow current decay and contributing to a nonvolatile memory current. To validate the photon-modulated electrochemical doping, first an in-situ spectroscopic experiment is performed before and after light exposure. The experimental setup is illustrated in FIG. 3b inset (FIG. 3b, otherwise provides a graph of absorbance vs. wavelength in nm), where an optical fiber was positioned above the channel to monitor its absorbance change, and the setup was evaluated using spectroelectrochemistry experiment shown in FIG. 3i. A 60-seconds light exposure at 7.0 mW/cm² was applied to the device under specific applied voltage. As described previously, a nonvolatile current could be detected in response to the light illumination. Here, corresponding to this nonvolatile current change, a spectrum shift of the photoactive layer was observed after the light illumination. As shown in FIG. 3b, a decrease in the visible region and an increase at NIR region was observed in the spectrum, which suggests the photon-modulated doping of the photoactive materials. After the light exposure, the device spectrum can be recovered to pristine states with the application of a reverse gate voltage, suggesting that there is no irreversible photooxidation.

FIG. 3c is a schematic illustration of a five-electrode electrochemical cell, where two extra electrodes (E1, E2, e.g., Pt electrodes) are added to the POECT device of the present disclosure to monitor the ion migration. FIG. 3d provides simultaneous channel current change (I_{DS}) in μA and open circuit potential (OCP_{E1/E2}) in V both vs. time in seconds showing change in response to light illumination. FIG. 3e is a graph showing PCBM anion radical/polaron transient absorption decay kinetic trace of pristine P₃HT/PCBM film (blue) and the film with electrolyte (red). The plots are normalized to facilitate comparison. FIG. 3f provides a graph of −I_{DS} in μA vs. V_{G} in Volts showing the transfer characteristics of the device. FIG. 3g is a graph of −ΔI_{DS} in μA vs. time in seconds providing an illustration of photonic response at V_{G}=−0.6 V and V_{DS}=−0.8 V of the device in different electrolytes. FIG. 3h is a graph of −I_{DS} in μA vs. time in seconds providing an illustration of photonic response of the device to hand waves in an ambient light environment with LiPF₆ based gel electrolyte. The purple areas indicate the periods when the device was repeatedly exposed to ambient light during the hand waves.

Referring to FIG. 3j, a graph of absorbance vs. wavelength in nm is provided illustrating that the photon-modulated electrochemical doping is accompanied by ion transport. To prove the existence of ion transport in response to light illumination, a five-electrode electrochemical cell as shown in FIG. 3c was fabricated. In the device, two extra Pt electrodes (E1, E2) were inserted in electrolyte solution and placed close to channel and gate, respectively. While a photon induced drain current (I_{DS}) is recorded at specific voltages (V_{G}=−0.6 V V_{DS}=−0.8 V), the open circuit potential (OCP) between these two Pt electrodes (E1, E2) was monitored simultaneously. As shown in FIG. 3d, there is an obvious open circuit potential change across the two electrodes in response to light illumination. This indicates that ion migration occurs, and a displaced ion concentration gradient builds up between the electrodes. The photon-induced ion migration, along with in-situ spectroscopic experiment, proves the existence of photon-modulated electrochemical doping. In addition, we observed that light-induced OCP change is in a good agreement with photon-induced channel current change, suggesting the photonic response is an ion diffusion-dependent process. We also note that with limited ion diffusion to channel, the photocurrent of P₃HT/PCBM film is small as shown in FIG. 3k which is a graph of −I_{DS} in μA vs. time in seconds illustrating the photonic response to three light pulses at various gate voltages: At gate voltage of 0 V, where the ion diffusion (TFSI−) is limited, a negligible current change was recorded. The next inquiry is about what is the ion effect on photocurrent generation. To answer this, the electrolyte effect on photophysical processes of the channel materials using pump-probe femtosecond transient absorption (TA) was investigated. A TA spectra was obtained with an excitation pulse of 532 nm as provided in FIGS. 3l (which is a schematic illustration of transient spectroscopy measurement) and 3m (which are graphs of transient spectra of P₃HT/PCBM and P₃HT/PCBM/electrolyte at various decay times and decay dynamics of P₃HT/PCBM and P₃HT/PCBM/electrolyte which are fitted using triexponential equations with a constant non-decaying component). Fitting parameters are shown in Table 1.

TABLE 1
Kinetic values obtained by a triexponential fit of the decay at 1049 nm^{a}

| λ_{probe (nm)} | Film | τ₁(ps)/(% A) | | τ₂(ps)/(% A) | | τ₃(ps)/(% A) | | Offset(% A) | |
|---|---|---|---|---|---|---|---|---|---|
| 1049 | P3HT/PCBM | 0.2 | (86.2) | 3.6 | (9.2) | 125 | (2.8) | 3.4E−4 | (1.8) |
| 1049 | P3HT/PCBM/Elec | 1.2 | (56.7) | 23 | (25.5) | 264.6 | (10) | 4.2E−4 | (7.8) |

^{a}Fit formula, Y = A1*exp(−t/τ1) + A2*exp(−t/τ2) + A3*exp(−t/τ3) + A_{offset}

FIGS. 3l and 3m show that both films, P₃HT/PCBM with and without electrolyte, initially displayed broad absorption band at about 1300 nm after photoexcitation, which decays rapidly on the picosecond time scale. A relatively long-lived absorption band was observed at about 1000 nm at a later time stage. It should be noted that the peak at about 1300 nm can be ascribed to the P₃HT singlet exciton and the one at about 1000 nm to the PCBM anion radical with a contribution from P₃HT polaron. To probe the electrolyte effect on these charge carriers' lifetime, the decay dynamics of the polaron/PCBM anion radical peak at 1049 nm was compared for the pristine film and the film with electrolyte. As shown in FIG. 3e, the signal of the film with electrolyte decays more slowly than that of pure film (without electrolyte). The decay traces were also fit and quantified to a tri-exponential function with a constant non-decaying component (offset), as depicted in FIG. 3m, and as mentioned the fitting parameters are summarized in Table 1. The results show that the lifetime of the charge-separated states in P₃HT/PCBM film is much longer in the presence of electrolyte, accounting for a higher photocurrent. These findings are consistent with our observations in device performance (higher photocurrent in channel is observed with promoted ion migration) and thus further support the working principle of the photonic synaptic behaviors.

Considering the photonic response is highly related to ion diffusion, we further studied the POECT device response with different electrolyte: Lithium hexafluorophosphate (LiPF₆), Lithium bis(trifluoromethanesulfonyl)imide (LiTFSI), and Tetrabutylammonium chloride (TBACl: (C₄H₉)₄NCl)). As shown in FIG. 3f, the drain current as well as threshold voltages of the devices varies with electrolyte in transfer curve. This is mainly due to the fact that different dopant anions have various doping densities and requires different potentials to be injected into the channel. Thus, this difference will also be reflected in photonic response. As shown in FIG. 3g, under the same applied voltage and light illumination, the device with Cl anion did not display any photonic response, since Cl⁻ cannot effectively permeate into and dope the film. On the other hand, in the presence of PF₆, the device exhibited the largest photocurrent since PF₆⁻ can easily penetrate the polymer and perturb the electrochemical doping. The significant photo response enables the device to respond to fast writing pulses (120 μs) while retaining distinguishable states, as shown in FIG. 3n which is a graph of −ΔI_{DS} in μA vs. time in seconds, in which drain current in response to fast light pulses. It should be noted that when conjugated polymers are immersed in concentrated LiPF₆, solvent and anions can spontaneously penetrate the polymer and form extended double layer, which may favor the electron depletion. Thus, when LiPF₆ was employed as the electrolyte, the device exhibited a considerable current in response to the ambient light without any gate voltage stress. As demonstrated in FIG. 3h, the device shows a sensible response to the hand waves, where the device was repeatedly exposed to the ambient light. Besides ambient light detection, we also show that the device is capable of responding to more dime light as shown in FIG. 3o in which a graph of −ΔI_{DS} in nA vs. time in seconds is provided illustrating photonic response to light pulses with light intensity of 6 μw/cm². This again demonstrated the importance of anion transport in photonic response and memory effects. Cations have less effect on the device performance as investigated as shown in FIG. 3p which provides graphs of absolute value of I_{DS} in μA vs. V_{G} in volts and a graph of −ΔI_{DS} in μA vs. time in seconds are provided illustrating photonic response to light pulses with light intensity of 6 μw/cm². Table 2 provides the ionic radii for four different cations.

To study the cation influence on synaptic behavior, we chose four different cations with various ionic radius and paired them with the same anion (TFIS⁻) for the device test. These four cations are: Li⁺, Na⁺, tetramethylammonium (TEA⁺), tetrabutylammonium (TBA⁺) and their ionic radius are shown in Table 2. According to transfer curve in FIG. 3p (i.e., the graph of I_{DS} vs. V_{G}), the device shows similar threshold voltage and current with Li⁺, Na⁺, TEA⁺, which indicates the channel material experiences similar doping behaviors with these four cations. This is due to the fact that electrochemical doping of the channel materials mainly needs anion for charge compensation. As a result, the cation has less impact on the OECT performance. Accordingly, the photonic responses of the device are also similar with these three cations, as shown in FIG. 3p (i.e., in the −ΔI_{DS} vs time graph). However, when TBA⁺ was used in electrolyte, the threshold voltage negatively shifted and drain current reduced in the transfer curve in comparison to the other three cations. This is mostly due to the especially large radius of TBA⁺ causing high hydrodynamic resistance in the electrolyte and limiting the ionic mobility/conductivity. This trend is also reflected in photonic response, as TBA⁺ has the smallest photonic response and memory.

TABLE 2
The ionic radii of four different cations

| Cation | Ionic radii, r/nm |
|---|---|
| Li+ | 0.069 |
| Na+ | 0.102 |
| TEA+ | 0.337 |
| TBA+ | 0.413 |

Referring to FIG. 4, a network of the POECT devices of the present disclosure is shown in connectivity with each other to form an array for various applications. The POECT devices are disposed in rows and columns. The gates and drains of the POECT devices in each row is coupled to each other while the sources of the POECT devices in each column are coupled to each other. This configuration allows the POECT devices to be operated as an array, in such applications as a memory array.

Referring to FIG. 5b, the footprint of the POECT device is further reduced with optical lithography technique since a high-density array is required for future higher resolution image perception and memorization. As shown in FIG. 5a, we fabricated a device array with 18,000 transistors on a 2.5×5 cm² glass substrate in a manner similar to FIG. 4. The channel length and width of each device in the array are 10 μm and 50 μm, respectively. The device fabrication process is illustrated in FIG. 5b. To reduce the device footprint, we first used a typical photolithography for microelectrode patterning, as shown in FIG. 5b processes (1)-(3). Then a crosslinker molecule, bis(fluorophenyl azide) (bisFA), was blended with P₃HT/PCBM (25 mg/mL in chloroform) at a weight ratio of 5% for channel materials printing, as shown in FIG. 5b processes (4) to (6).

In operation, the POECT device of the present disclosure is operated in the following manner. 1) the device turns on (i.e., establish I_{DS}), 2) after applying light I_{DS} modulates (i.e., enhances I_{DS}), 3) light is removed with V_{G} on, 4) establishing memory (I_{DS} difference between before and after light stimulation), and 5) repeat 2-3 to further establish memory.

Those having ordinary skill in the art will recognize that numerous modifications can be made to the specific implementations described above. The implementations should not be limited to the particular limitations described. Other implementations may be possible.

1. A photonic-organic electrochemical transistor (POECT), comprising:
a substrate;
three terminals including a gate, a drain, and a source disposed over the substrate, wherein the space between the drain and the source forms a channel; and
an electrolyte in fluid and electrical communication with the gate and the channel;
wherein the channel is formed of a photoactive layer composed of donor-acceptor bulk-heterojunction interfaces.

2. The POECT device of claim 1, wherein the substrate is selected from the group consisting of glass, silicon, parylene, polyethylene, and a combination thereof.

3. The POECT device of claim 1, wherein each of the three terminals are is formed of a metal.

4. The POECT device of claim 3, wherein the metal is selected from the group consisting of platinum, Au, ITO, Ag, Cu, and a combination thereof.

5. The POECT device of claim 1, wherein the electrolyte is selected from the group consisting of Lithium hexafluorophosphate (LiPF₆), Lithium bis(trifluoromethanesulfonyl)imide (LiTFSI), and Tetrabutylammonium chloride (TBACl: (C₄H₉)₄NCl)), and a combination thereof.

6. The POECT device of claim 1, wherein the photoactive layer is composed of donor-acceptor bulk-heterojunction interfaces includes poly(3-hexylthiophene) (P₃HT) and [6,6]-phenyl C61-butyric acid methylester (PCBM).

7. The POECT device of claim 1, wherein application of voltage to the gate terminal, turns on the POECT device thereby allowing a drain to source current when the drain terminal is coupled to a voltage source having a magnitude and the source terminal is coupled to ground.

8. The POECT device of claim 7, wherein application of light to the channel, results in an enhancement of the drain to source current.

9. The POECT device of claim 8, wherein removal of the light applied to the channel, results in a device memory to the enhanced drain to source current.

10. The POECT device of claim 9, wherein the device memory is erased by applying a voltage to the gate terminal.

11. The POECT device of claim 8, wherein the drain to source current is selectively influenced based on the voltage placed on the gate voltage.

12. The POECT device of claim 8, wherein the drain to source current is selectively influenced based on the magnitude of the source voltage coupled to the drain.

13. The POECT device of claim 8, wherein the drain to source current is selectively influenced based on intensity of light applied to the channel.

14. The POECT device of claim 8, wherein the drain to source current is selectively influenced based on wavelength of light applied to the channel.

15. The POECT device of claim 8, wherein the drain to source current is selectively influenced based on selection of material of the electrolyte.
